(19) United States
(12) Patent Application Publication
(10) Pub. No.: US 2014/0065549 A1
(43) Pub. Date: Mar. 6, 2014

(54) DRAWING APPARATUS AND METHOD OF MANUFACTURING ARTICLE

(71) Applicant: CANON KABUSHIKI KAISHA, Tokyo (JP)

(72) Inventors: Takahiro Nakayama, Albany, NY (US); Kentaro Sano, Utsunomiya-shi (JP)

(73) Assignee: CANON KABUSHIKI KAISHA, Tokyo (JP)

(21) Appl. No.: 13/971,901

(22) Filed: Aug. 21, 2013

(30) Foreign Application Priority Data
Aug. 28, 2012 (JP) 2012-188071

(51) Int. Cl. H01J 37/30

(52) U.S. Cl. CPC H01J 37/3007
USPC 430/296; 250/492.3

(57) ABSTRACT

The present invention provides a drawing apparatus for performing drawing on a substrate using a plurality of charged particle beams, the apparatus including an aperture array including an opening region including a region in which a plurality of openings are formed to generate the plurality of charged particle beams, and a peripheral region surrounding the opening region, wherein the aperture array has a shielding structure for shielding at least part of an electric field generated by charging of a contaminant in the peripheral region with respect to the plurality of charged particle beams passing through the plurality of openings.

### BACKGROUND OF THE INVENTION

1. Field of the Invention

The present invention relates to a drawing apparatus and a method of manufacturing an article.

2. Description of the Related Art

There is known a drawing apparatus for drawing (transferring) a micropattern on a substrate using a charged particle beam as one of the apparatuses used in the manufacturing processes of semiconductor devices and the like. In the drawing apparatus, a gas contained in the internal atmosphere of the drawing apparatus is decomposed upon irradiation of the charged particle beam, and a contaminant is produced (deposited) on a member such as an aperture array irradiated with the charged particle beam (contamination). An example of such a contaminant is carbon (film). The contamination is caused by a carbon compound emitted from an outgas emitted from the components of the drawing apparatus and a resist (photosensitive material) applied to the substrate.

The contaminant deposited on the aperture array is irradiated with the charged particle beam or secondary electrons generated by the charged particle beam to be positively or negatively charged, thereby applying the attractive or repulsive force to the charged particle beam. For this reason, the charged particle beam may shift from a target track. Techniques for suppressing deposition of contaminants on the aperture array and the like are proposed in literature 1 (B. V. Yashinskiy et. al., Proc. of SPIE Vol. 6921, 14, 2008) and literature 2 (S. B. Hill et. al., Proc. of SPIE Vol. 7636, OE, 2010). Literature 1 discloses a technique for suppressing deposition of the contaminant by irradiation of the charged particle beam while introducing an oxidizing gas (oxygen). Literature 2 discloses a technique for suppressing the deposition of the contaminant by irradiation of an EUV (Extreme Ultra Violet) beam while introducing an oxidizing gas (water vapor).

According to the related arts, however, when the intensity (illuminance) of the charged particle beam or EUV beam is low, the deposition of the contaminant cannot be sufficiently suppressed. Therefore, in the aperture array, contaminants are deposited in a region where the intensity of the charged particle beam is low, that is, at the edge of the region irradiated with the charged particle beam.

### SUMMARY OF THE INVENTION

The present invention provides a drawing apparatus advantageous to reduction of an influence of charging of contaminants.

According to one aspect of the present invention, there is provided a drawing apparatus for performing drawing on a substrate using a plurality of charged particle beams, the apparatus including an aperture array including an opening region including a region in which a plurality of openings are formed to generate the plurality of charged particle beams, and a peripheral region surrounding the opening region, wherein the aperture array has a shielding structure for shielding at least part of an electric field generated by charging of a contaminant in the peripheral region with respect to the plurality of charged particle beams passing through the plurality of openings.

Further features of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus according an aspect of the present invention.

FIG. 2 is a graph showing intensity dependences of the charged particle beams of the removal rates of contaminants deposited on aperture arrays and the deposition rates of contaminants deposited on the aperture arrays.

FIG. 3 is a view showing a charged particle beam intensity distribution formed on the aperture array and contaminants deposited on the aperture array in the drawing apparatus in FIG. 1.

FIG. 4 is a graph illustrating the intensity distribution of the charged particle beam shown in FIG. 3.

FIG. 5 is a view illustrating part of the first aperture array of the drawing apparatus shown in FIG. 1.

FIG. 6 is a view illustrating the section of part of the first aperture array of the drawing apparatus shown in FIG. 1.

FIG. 7 is a view showing an example of a groove formed in the peripheral region of the first aperture array of the drawing apparatus shown in FIG. 1.

FIG. 8 is a view showing an example of grooves formed in the peripheral region of the first aperture array of the drawing apparatus shown in FIG. 1.

FIG. 9 is a view showing an example of a convex member disposed in an opening region of the first aperture array of the drawing apparatus shown in FIG. 1.

FIG. 10 is a view showing an example of a groove formed in the peripheral region and a convex member disposed in an opening region of the first aperture array of the drawing apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

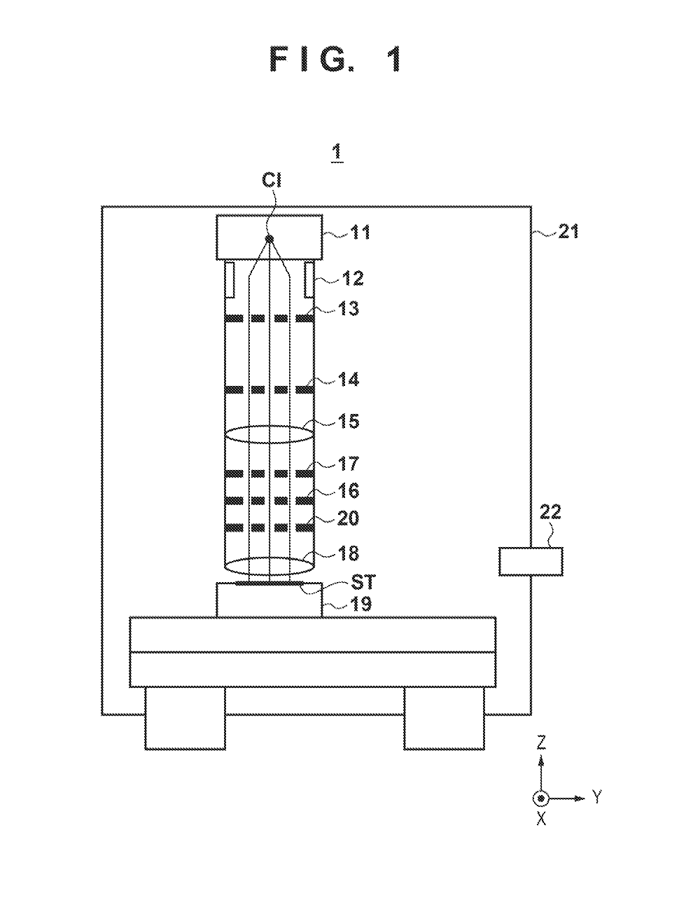

FIG. 1 is a schematic view showing the arrangement of a drawing apparatus 1 according to an aspect of the present invention. The drawing apparatus 1 is a lithography apparatus for drawing a pattern on a substrate using a charged particle beam (electron beam) (that is, for forming a latent image pattern on a photosensitive material on the substrate).

The drawing apparatus 1 includes a charged particle source 11, collimator lens 12, first aperture array 13, second aperture array 14, first electrostatic lens array 15, stopping aperture array 16, and blanker array 17. The drawing apparatus 1 also includes a second electrostatic lens array 18, stage 19, deflector 20, chamber 21, and exhaust system 22.

The charged particle source 11 forms a crossover image CI. A charged particle beam emitted from the crossover image CI is substantially collimated through the collimator lens 12 and enters the first aperture array 13. The first aperture array 13 includes a plurality of openings (for example, circular openings) in a matrix. The charged particle beam entering the first aperture array 13 is split into a plurality of charged particle beams by the plurality of openings.

The charged particle beams having passed through the first aperture array 13 enter the second aperture array 14. The second aperture array 14 includes a plurality of openings (for example, circular openings) in correspondence with the plurality of openings of the first aperture array 13. The charged particle beams split by the first aperture array 13 are further split into a plurality of charged particle beams by the plurality of openings of the second aperture array 14.

The charged particle beams having passed through the second aperture array 14 enter the first electrostatic lens array 15 having a circular opening. The first electrostatic lens array 15 generally includes three electrode plates. The three electrode plates are integrally illustrated in FIG. 1.

The stopping aperture array 16 having fine openings arrayed in a matrix is disposed at a position where the charged particle beams having passed through the first electrostatic lens array 15 form the first crossover image. The blanker array 17 performs a blanking operation accompanying blocking of the charged particle beams in the stopping aperture array 16.

The charged particle beams having passed through the stopping aperture array 16 are focused by the second electrostatic lens array 18 to form a crossover image (not shown) on a substrate SB such as a wafer or mask. The second electrostatic lens array 18 can be formed from three electrode plates as in the first electrostatic lens array 15.

To draw a pattern, the deflector 20 deflects the crossover image on the substrate SB in the Y-axis direction and the blanker array 17 performs the blanking operation while continuously moving (scanning) the stage 19 holding the substrate SB in the X-axis direction. In this case, deflection (scanning) of the crossover image by the deflector 20 is performed using, as a reference, a distance measuring result of the stage 19 obtained in real time by a laser interferometer.

The above-mentioned components (that is, the charged particle source 11 to the deflector 20) are housed in (inside) the chamber 21. In the drawing apparatus 1, the interior of the chamber 21 is evacuated through the exhaust system 22 made of a vacuum pump to form a vacuum environment (a pressure equal to or less than 1×10⁻⁵ Pa) inside the chamber 21. An optical system space in which the charged particle optical system (an optical system from the collimator lens 12 to the second electrostatic lens array 18 in FIG. 1) for guiding the charged particle beam to the substrate ST is arranged requires a high vacuum degree. Therefore, an exhaust system may be arranged in the optical system space independently of a stage space in which the stage 19 is arranged and gases are produced in large amounts.

In the drawing apparatus 1, deposits such as contaminants may be deposited on the first aperture array 13 and the second aperture array 14 upon repeating irradiation of the charged particle beams (that is, pattern drawing). An example of such a contaminant is carbon. The contamination is caused by a carbon compound emitted from the outgas emitted from the components of the drawing apparatus 1 and a resist applied to the substrate ST. The contaminant is irradiated with the charged particle beam or secondary electrons generated by the charged particle beam to be positively or negatively charged, thereby applying the attractive or repulsive force to the charged particle beams passing through (openings of) the first aperture array 13 and the second aperture array 14. For this reason, the charged particle beam may shift from a track (target track).

On the other hand, the vacuum atmosphere is formed inside the chamber 21, and hydrogen and water vapor remain in it. When the atmosphere containing hydrogen and water vapor is irradiated with the charged particle beams, the deposition of carbon-based contaminants can be suppressed. The first aperture array 13 is spaced apart from the substrate ST and is not so influenced by the carbon compound originating from the resist applied to the substrate. However, the first aperture array 13 is close to the charged particle source 11 and is irradiated with the charged particle beams having a high intensity (illuminance).

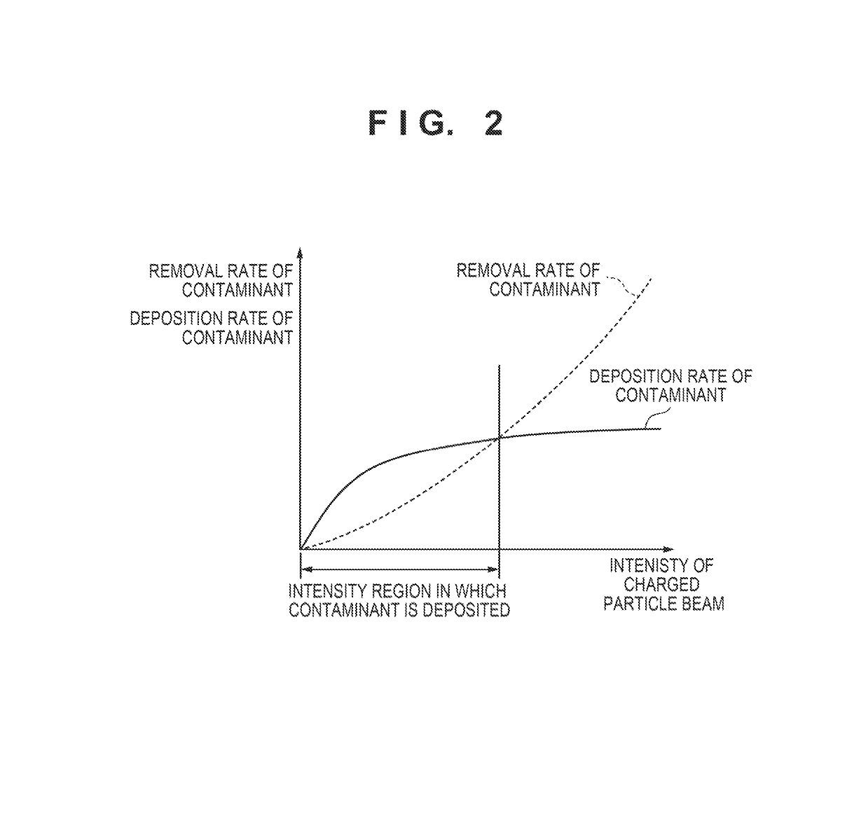

FIG. 2 is a graph showing intensity dependences of the charged particle beams of the removal rates of contaminants deposited on the first aperture array 13 and the second aperture array 14 and the deposition rates of contaminants deposited on the first aperture array 13 and the second aperture array 14. Referring to FIG. 2, the removal rates and deposition rates of the contaminants are plotted along the ordinate, and the intensities of the irradiation charge particle beams are plotted along the abscissa. Referring to FIG. 2, when the intensity of the charged particle beam is high, the deposition suppression effect of the contaminants by hydrogen and water vapor is obviously high. The contaminant is deposited in a region (intensity region) having an intensity lower than the intensity (intensity value) of the charged particle beam corresponding to an intersection between a curve indicating the removal rate of the contaminant and a curve indicating the deposition rate of the contaminant.

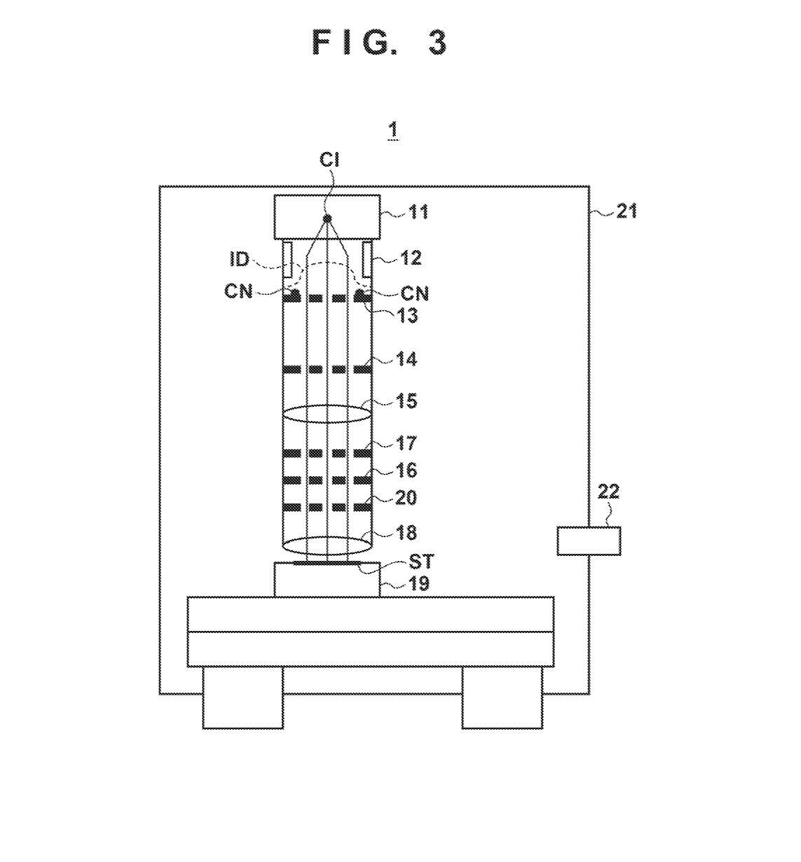

In the drawing apparatus 1, the charged particle beam from the charged particle source 11 forms an intensity distribution ID on the first aperture array 13, as shown in FIG. 3. FIG. 4 is a graph illustrating the intensity distribution ID formed on the first aperture array 13. Referring to FIG. 4, the intensity of the charged particle beam is plotted along the ordinate, while the position on the first aperture array is plotted along the abscissa. As shown in FIGS. 3 and 4, a contaminant CN is deposited in a region (low intensity region) where the intensity of the charged particle beam is low. In this manner, the charged particle beams irradiating the first aperture array 13 have the intensity distribution ID. The contaminant NC is deposited on the first aperture array 13 in the low intensity region.

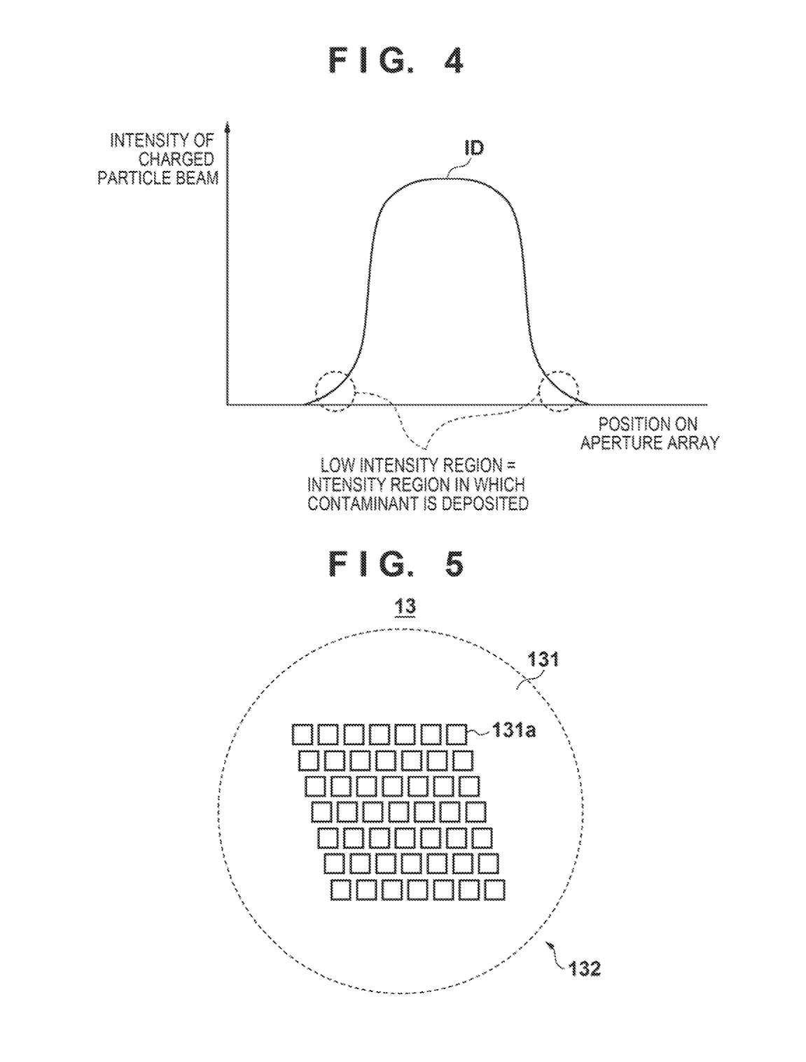

FIG. 5 is a view illustrating part of the first aperture array 13. The first aperture array 13 includes an opening region 131 including a region in which a plurality of openings 131a for splitting the charged particle beam from the charged particle source 11 into a plurality of charged particle beams (that is, the openings through which the charged particle beam passes), and a peripheral region 132 surrounding the opening region 131. The intensity of the charged particle beam in the peripheral region 132 is lower than that in the opening region 131. For example, the intensity of the charged particle beam in the peripheral region 132 is less than the half the maximum intensity of the charged particle beam in the opening region 131. The deposition suppression effect of the contaminant by hydrogen and water vapor depends on the intensity of the charged particle beam, as described above. The deposition of the contaminant CN progresses in the region where the intensity of the charged particle beam on the first aperture array 13 is low, that is, in the peripheral region 132.

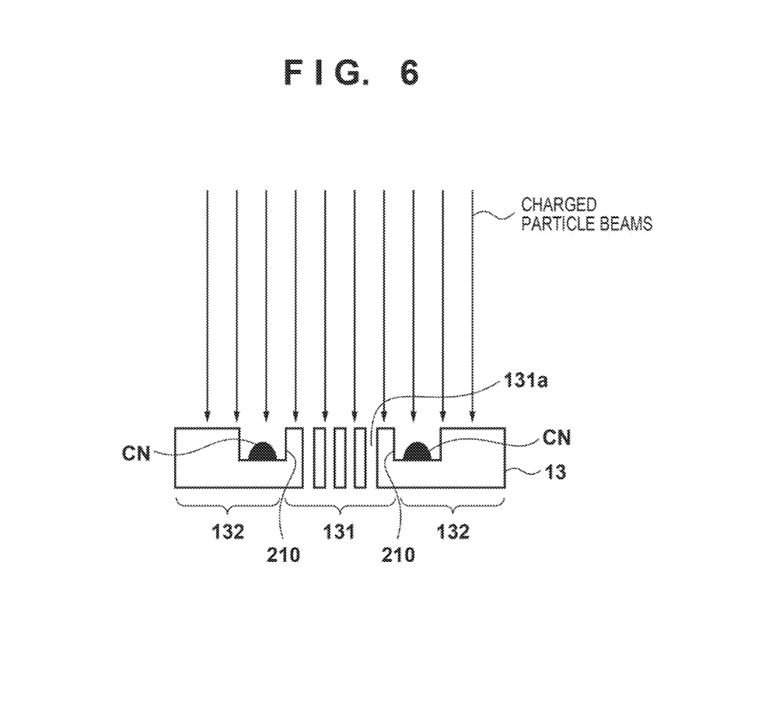

FIG. 6 is a view illustrating the section of part of the first aperture array 13. Referring to FIG. 6, the contaminant CN is deposited in the peripheral region 132 where the intensity of the charged particle beam on the first aperture array 13 is low. In this embodiment, a conductive groove 210 is formed in the peripheral region 132 as a structure for reducing the influence on the plurality of charged particle beams passing through the plurality of openings 131a, which influence is caused by charging, upon irradiation of the charged particle beams, the contaminant CN deposited in the peripheral region 132. In other words, the first aperture array 13 has a shielding structure for shielding at least part of the electric field generated by charging of the contaminant CN in the peripheral region 132 with respect to the charged particle beams passing through the plurality of openings 131a. When the charged particle beams are viewed from the contaminant CN, at least part of the groove 210 limits the viewing range. As described above, the contaminant CN is charged upon irradiation of the charged particle beams to change the surrounding electric field and apply the attractive or repulsive force to the charged particle beams. For this reason, the charged particle beams passing through the openings 131a shift from the target track. To solve this problem, according to this embodiment, at least part of the groove 210 reduces the influence (attractive or repulsive force) on the charged particle beams by the electric field derived from charging of the contaminant CN.

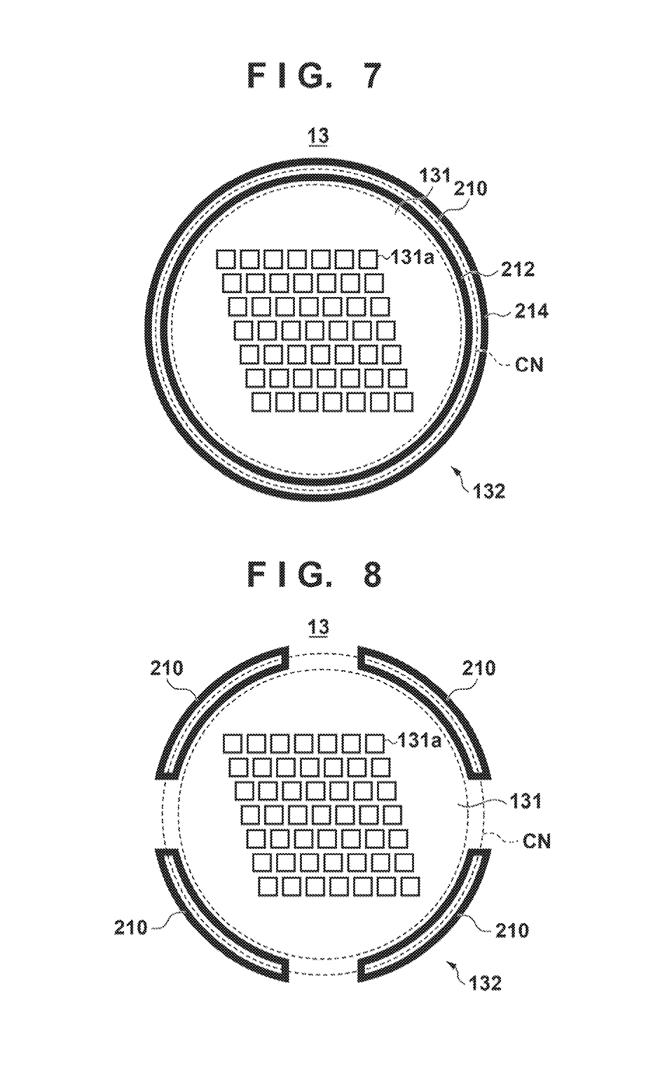

FIG. 7 is a view showing an example of the groove 210 formed in the peripheral region 132 of the first aperture array 13. As shown in FIG. 7, the groove 210 is formed as an annular groove surrounding the opening region 131. A groove inner wall 212 and a groove outer wall 214 of the groove 210 are formed to sandwich the contaminant CN (that is, sandwich the positions where the contaminant CN is deposited). The groove inner wall 212 limits the range in which the contaminant CN views the charged particle beams passing through the openings 131a of the first aperture array 13. The groove inner wall 212 reduces the influence (attractive or repulsive force) of the charging of the contaminant CN on the charged particle beams. In FIG. 7, the groove 210 is continuously formed along the annular closed curve, but is not limited to this. For example, as shown in FIG. 8, a plurality of grooves 210 are partially (discontinuously) formed along the annular closed curve.

When the conductive groove 210 is formed in the peripheral region 132 of the first aperture array 13 as described above, the influence of the electric field by charging of the contaminant CN deposited in the peripheral region 132 can be reduced. That is, the influence (attractive or repulsive force) on the charged particle beams by charging of the contaminant CN is reduced, and shift of the charged particle beams from the target track can be prevented or reduced. Therefore, the drawing apparatus 1 can achieve excellent drawing precision. The drawing apparatus 1 can reduce the cleaning frequency of the contaminant CN, obtaining an advantage to productivity.

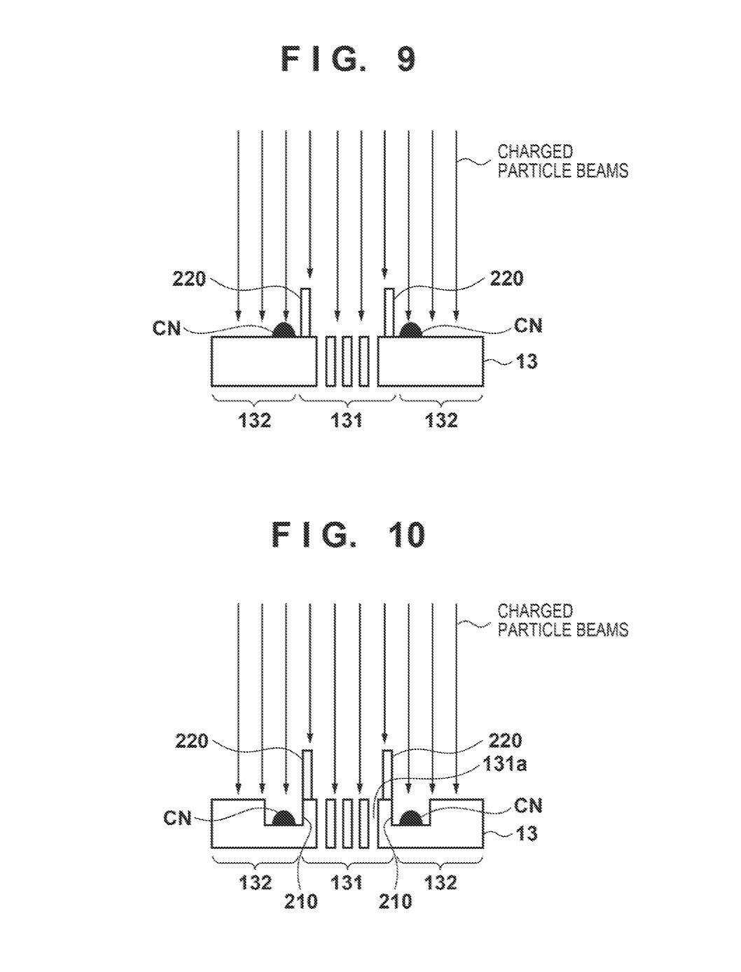

The structure for reducing the influence on the plurality of charged particle beams passing through the plurality of openings 131a, which influence is caused by charging of the contaminant CN deposited in the peripheral portion 132, is not limited to the groove 210 formed in the peripheral region 132. For example, the structure for reducing the influence on the plurality of charged particle beams passing through the plurality of openings 131a, which influence is caused by charging of the contaminant CN, may be a convex member 220 disposed as an annular member around (edge) the opening region 131 of the first aperture array 13, as shown in FIG. 9. The convex member 220 is conductive, and at least part of the convex member 220 limits the viewing range when the electron beams are viewed from the contaminant CN. The reason why the convex member 220 is disposed in the opening region 131 (that is, a region in which the intensity of the charged particle beam is high) is to prevent or reduce deposition of the contaminant CN on the convex member 220 upon irradiation of the charged particle beams. The convex member 220 is connected to ground (that is, grounded) and has the same potential as that of the first aperture array 13. For this reason, the convex member 220 is not charged upon irradiation of the charged particle beams, and the charged particle beams are not adversely affected.

As shown in FIG. 10, the structure for reducing the influence on the plurality of charged particle beams passing through the plurality of openings 131a, which influence is caused by charging of the contaminant CN, may be a combination of the groove 210 formed in the peripheral region 132 and the convex member 220 disposed in the opening region 131. The deeper the groove 210, the better the effect. However, the depth of the groove 210 is limited to maintain the mechanical strength of the first aperture array 13. By combining the groove 210 and the convex member 220, the convex member 220 can effectively reduce the influence (attractive or repulsive force) caused by charging of the contaminant CN while suppressing an increase in depth of the groove 210.

According to this embodiment, the structure for reducing the influence on the plurality of charged particle beams passing through the plurality of openings 131a, which influence is caused by charging of the contaminant CN, is applied to the first aperture array 13. However, this structure is also applicable to the second aperture array 14. The second aperture array 14 includes a plurality of openings (subaperture set) in correspondence with the plurality of openings of the first aperture array 13. Therefore, the structure (the same structure of at least one of the groove 210 and the convex member 220) for reducing the influence of the charging of the contaminant CN on the plurality of charged particle beams passing through the subaperture set is provided for each subaperture set.

The drawing apparatus 1 of this embodiment is suitable for manufacturing various articles including a micro device such as a semiconductor device and an element having a microstructure. The method of manufacturing an article according to this embodiment includes a step of forming a latent image pattern on a resist, applied onto a substrate, using the drawing apparatus 1 (a step of performing drawing on a substrate), and a step of developing the substrate having the latent image pattern formed on it in the forming step. This manufacturing method also includes subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of a device than the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-188071, filed Aug. 28, 2012, which is hereby incorporated by reference herein in its entirety.

What is claimed is:

1. A drawing apparatus for performing drawing on a substrate using a plurality of charged particle beams, the apparatus comprising:
an aperture array including an opening region including a region in which a plurality of openings are formed to generate the plurality of charged particle beams, and a peripheral region surrounding the opening region,
wherein the aperture array has a shielding structure for shielding at least part of an electric field generated by charging of a contaminant in the peripheral region with respect to the plurality of charged particle beams passing through the plurality of openings.

2. The apparatus according to claim 1, wherein an intensity of a charge particle beam in the peripheral region is lower than that in the opening region.

3. The apparatus according to claim 1, wherein an intensity of a charged particle beam in the peripheral region is not more than half a maximum intensity of a charged particle beam in the opening region.

4. The apparatus according to claim 1, wherein the shielding structure includes a groove formed in the peripheral region.

5. The apparatus according to claim 1, wherein the shielding structure includes a convex member disposed at an edge of the opening region.

6. The apparatus according to claim 1, wherein the shielding structure includes a groove formed in the peripheral region and a convex member disposed at an edge of the opening region.

7. A method of manufacturing an article, the method comprising:
performing drawing on a substrate using a drawing apparatus; and
developing the substrate on which the drawing has been performed,
wherein the drawing apparatus performs drawing on the substrate using a plurality of charged particle beams, and includes:
an aperture array including an opening region including a region in which a plurality of openings are formed to generate the plurality of charged particle beams, and a peripheral region surrounding the opening region,
wherein the aperture array has a shielding structure for shielding at least part of an electric field generated by charging of a contaminant in the peripheral region with respect to the plurality of charged particle beams passing through the plurality of openings.
